(19) United States
(12) Patent Application Publication
(10) Pub. No.: US 2012/0160671 A1
(43) Pub. Date: Jun. 28, 2012

(54) SPUTTERING DEVICE

(75) Inventors: Hiraku Ishikawa, Sendai City (JP); Yuji Ono, Sendai City (JP); Teruyuki Hayashi, Sendai City (JP)

(73) Assignee: TOKYO ELECTRON LIMITED, Tokyo (JP)

(21) Appl. No.: 13/393,110

(22) PCT Filed: Aug. 25, 2010
(86) PCT No.: PCT/JP2010/064364

§ 371 Date: Feb. 28, 2012

(30) Foreign Application Priority Data
Sep. 1, 2009 (JP) 2009-201404

(51) Int. Cl. C23C 14/00

(52) U.S. Cl. 204/298.11

(57) ABSTRACT

Provided is a sputtering device which can achieve a sputtering while blocking light that enters from a sputtering space onto a substrate as an object to be sputtered on which an organic thin film is formed, thereby preventing the deterioration in properties of the organic thin film. Specifically provided is a sputtering device for achieving a sputtering of a substrate that is placed on the side of a sputtering space, wherein the sputtering space is formed between a pair of targets that are so placed as to face each other. The sputtering device comprises: an electric power source configured to apply a voltage between the pair of targets; a gas supply unit configured to supply an inert gas to the sputtering space; and a light-shielding mechanism configured to be placed between the sputtering space and the substrate.

### CROSS REFERENCE TO RELATED APPLICATIONS

This application is a national phase of PCT application No. PCT/JP2010/064364, filed 25 Aug. 2010, which claims priority to Japanese patent application No. 2009-201404, filed 1 Sep. 2009, all of which are incorporated herein by reference.

### TECHNICAL FIELD

The present invention relates to a sputtering device.

### BACKGROUND ART

In the related art, film forming of various metallic films or metallic compound films using a sputtering method has been widely known, and various sputtering methods and sputtering devices that form a sputter film have been proposed.

For example, Patent Document 1 discloses a sputtering device (a facing target sputtering device; FTS) in which an AC electric power source, that applies AC voltages having phases deviated from each other by 180° to two targets facing each other, is installed. FIG. 1 is a schematic cross-sectional view illustrating an example of a conventional sputtering device 100 in which an AC electric power source is installed. Although sputtering device 100 is generally installed inside a case which can be subjected to vacuum exhaustion, the case is omitted in FIG. 1.

As shown in FIG. 1, in sputtering device 100, two targets 105 and 106 made of, for example, aluminum (Al) or silver (Ag) are placed to face each other. An AC electric power source 110 is electrically connected to targets 105 and 106 through a circuit 107, and as a result, the AC voltages having the phases deviated by 180° are applied to targets 105 and 106. Further, magnets 112 and 113 are placed at both ends of targets 105 and 106 such that the different magnetic poles of the magnets face each other. In addition, a magnetic field is configured to be generated in a direction perpendicular to targets 105 and 106, in a sputtering space 115 which is a space between targets 105 and 106. Further, a substrate G which is a manufacturing target of a sputter film is placed on a lateral side of sputtering space 115. Substrate G is held by a substrate holding member (not shown) and is appropriately movable.

A gas supply unit 117 that supplies, for example, inert gas such as argon and further supplies oxygen or nitrogen to sputtering space 115 as necessary is placed at the other lateral side of sputtering space 115 where substrate G is not placed.

In conventional sputtering device 100 configured as described above, plasma is generated by an AC electric field in sputtering space 115 and constrained between targets 105 and 106 by the generated magnetic field. Inert gas supplied from gas supply unit 117 is ionized by the generated plasma and ions of the ionized inert gas collide with targets 105 and 106, and as a result, target materials which are spattered and scattered by the colliding are film-formed on substrate G to achieve sputtering.

### CITATION LIST

### Patent Document

Patent Document 1: Japanese Patent Application Laid-Open No. H11-29860

### SUMMARY OF INVENTION

### Technical Problem

However, in conventional sputtering device 100 having the above configuration, for example, when sputtering is performed with respect to substrate G on which an organic thin film has been already film-formed, ultraviolet rays having a short wavelength are leaked from sputtering space 115 to be irradiated to the organic thin film by generation of light depending on the generation of plasma in sputtering space 115, thereby exerting a bad influence on the organic thin film. It is considered as a reason that a characteristic of the organic thin film is deteriorated because, for example, the ultraviolet rays having the short wavelength break binding of organic molecules of the organic thin film when targets 105 and 106 are made of silver or aluminum.

Accordingly, by contriving the above problem, the present invention provides a sputtering device that blocks light from a sputtering space with respect to a substrate which is an object to be sputtered on which an organic thin film is formed, to perform sputtering while preventing a characteristic of the organic thin film from being deteriorated.

### Solution to Problem

According to the present invention, there is provided a sputtering device that performs a sputtering with respect to a substrate placed at a lateral side of a sputtering space formed between a pair of targets facing each other, including: an electric power source configured to apply voltage between the pair of targets; a gas supply unit configured to supply inert gas to the sputtering space; and a light-shielding mechanism configured to be placed between the sputtering space and the substrate.

### Advantageous Effects of Invention

According to the present invention, there is provided a sputtering device that blocks light from a sputtering space with respect to a substrate as an object to be sputtered on which an organic thin film is formed, to perform sputtering while preventing a characteristic of the organic thin film from being deteriorated.

### BRIEF DESCRIPTION OF DRAWINGS

FIG. 1 is a schematic cross-sectional view of a conventional sputtering device.

FIG. 2 is a schematic cross-sectional view of a sputtering device.

FIG. 3 is an enlarged view of a light-shielding mechanism.

FIG. 4 is an explanatory view illustrating a light-shielding mechanism according to a first modified example of the present invention.

FIG. 5 is an explanatory view illustrating a light-shielding mechanism according to a second modified example of the present invention.

FIGS. 6A and 6B are an explanatory view illustrating a light-shielding mechanism according to a third modified example of the present invention.

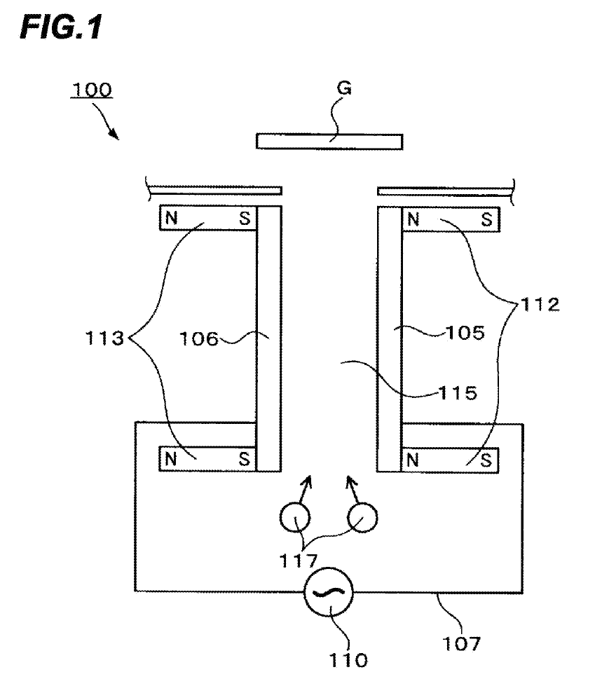

### DESCRIPTION OF EMBODIMENTS

Hereinafter, exemplary embodiments of the present invention will be described with reference to the accompanying drawings. In the specification and the accompanying drawings, the same reference numerals refer to components having the same functions and configurations, and as a result a duplicated description thereof will be omitted.

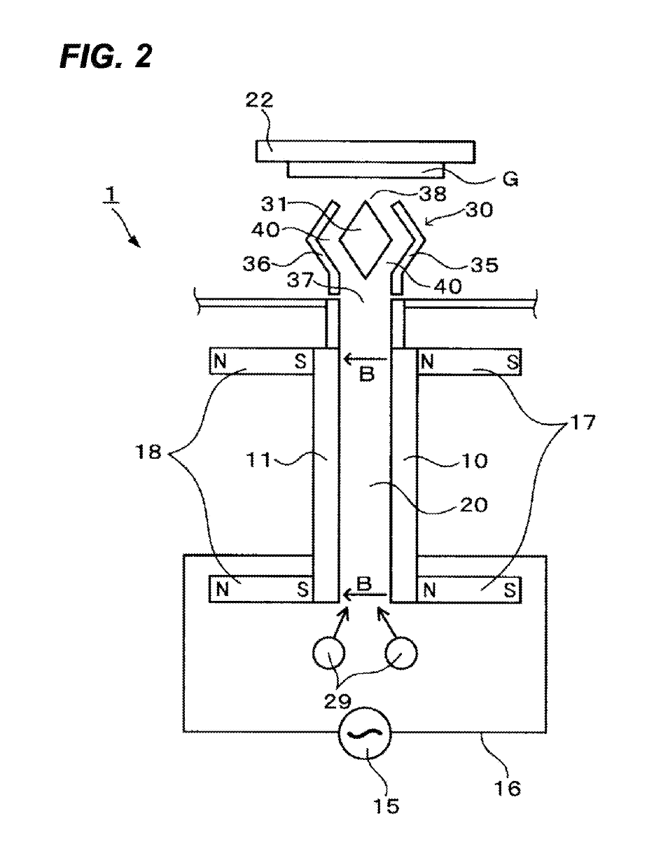

FIG. 2 is a schematic cross-sectional view of a sputtering device 1 that performs a sputtering with respect to a substrate G according to an exemplary embodiment of the present invention. Herein, sputtering device 1 is installed inside a case (not shown) which can be subjected to vacuum exhaustion. A pair of targets 10 and 11 made of, for example, aluminum (Al), silver (Ag), ITO or a transparent conductive material is placed to face each other in sputtering device 1. Further, an AC electric power source 15 that applies AC voltages having inverted phases to each other is connected to pair of targets 10 and 11 through a circuit 16. Herein, a frequency of AC electric power source 15 is, for example, in the range of 20 kHz to 100 kHz, and the AC voltages having the inverted phases are, for example, AC voltages having phases which are deviated from each other by 180°. Magnetic bodies (magnets) 17 and 18 are attached to ends of pair of targets 10 and 11 with different magnetic poles thereof facing each other and a magnetic field B is generated in a direction perpendicular to targets 10 and 11 in a sputtering space 20 between targets 10 and 11.

Further, substrate G which is an object to be sputtered is placed at one lateral side of sputtering space 20 while supported by a substrate supporting member 22. Herein, substrate G is supported so that a surface to be processed faces sputtering space 20. A gas supply unit 29 that supplies inert gas to sputtering space 20 is installed at the other lateral side of sputtering space 20 where substrate G is not placed. Herein, as the inert gas, for example, argon (Ar) is used. Since high voltage is applied to sputtering space 20 under vacuum, plasma is generated in sputtering space 20 by ionization of inert gas supplied from gas supply unit 29. The generated plasma is constrained to sputtering space 20 by magnetic field B generated by magnetic bodies 17 and 18.

In addition, a light-shielding mechanism 30 is placed between sputtering space 20 and substrate G. Light-shielding mechanism 30 includes a light blocking body 31 having a property to absorb or reflect light such as, for example, black alumite and aluminum, and a pair of shielding members 35 and 36 which are formed at both sides of light blocking body 31 while surrounding light blocking body 31 to prevent sputter particles scattered from sputtering space 20 from being dispersed and made of, for example, quartz. Light blocking body 31 is made of a material in which light does not penetrate, such as the black alumite or aluminum. A front end of light blocking body 31 facing sputtering space 20 has a tapered shape and for example, a cross-sectional shape of light blocking body 31 is a lozenge shape. Further, the width of light blocking body 31 is equal to or larger than the width (the width between targets 10 and 11) of sputtering space 20. Spaces formed between light blocking body 31 and shielding members 35 and 36 serve as passages 40 through which sputter particles pass, and passages 40 are formed at both lateral sides along two sides of the lateral side of light blocking body 31. Since the cross-sectional shape of light blocking body 31 is lozenge, passages 40 are curved spaces. An opening 37 at sputtering device 1 side and an opening 38 at substrate G side are formed between shielding member 35 and shielding member 36. Sputtering space 20 is in communication with passages 40 through opening 37, and opening 38 is opened toward the surface to be processed of substrate G.

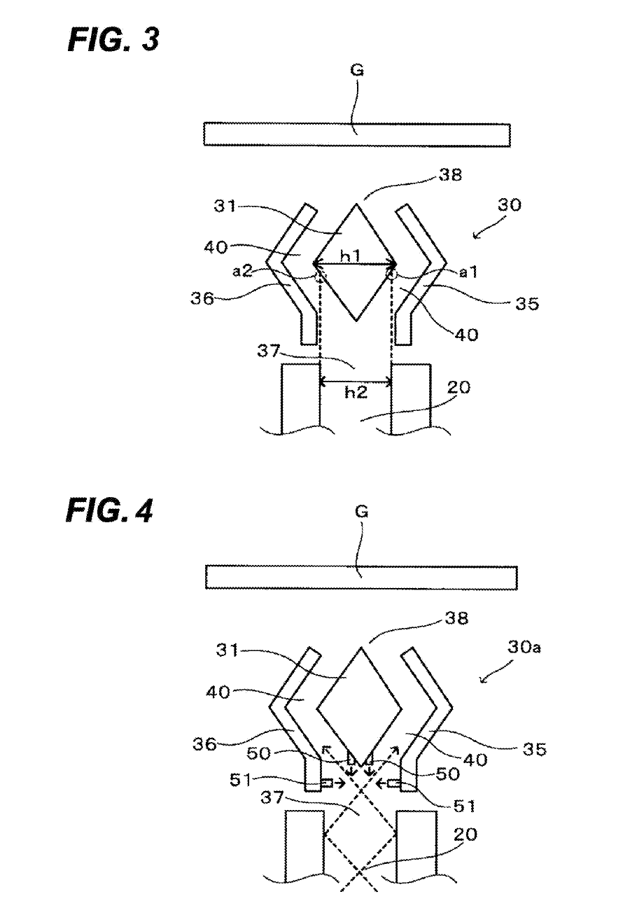

Herein, passages 40 have the curved shape, and the width of light blocking body 31 is equal to or larger than the width of sputtering space 20, and as a result, the positional relationships among substrate G, light blocking body 31, shielding members 35 and 36, and sputtering space 20 are configured as placement relationships in which sputtering space 20 cannot be viewed from substrate G by light blocking body 31 and shielding members 35 and 36. Hereinafter, the placement relationship will be described with reference to FIG. 3.

FIG. 3 is an enlarged view of light-shielding mechanism 30. Herein, a case where the cross-sectional shape of light blocking body 31 is lozenge will be described. As shown in FIG. 3, when the length of a diagonal line parallel to substrate G in the cross section of light blocking body 31 is represented by h1 and the width of sputtering space 20, that is, the length between the targets is represented by h2, and the lengths have the relationship of h1≧h2. That is, light from sputtering space 20 is irradiated to a portion inside cross points a1 and a2 of extension lines of inner surfaces of the targets and light blocking body 31, in light blocking body 31. Since the cross section of light blocking body 31 has the tapered shape toward the bottom of the device (downward in FIG. 3), light irradiated to light blocking body 31 is absorbed or reflected below the diagonal line parallel to substrate G in the cross section of light blocking body 31. Further, since shielding members 35 and 36 may be made of a material in which light penetrates as described above, light reflected by light blocking body 31 does not head toward substrate G by penetrating shielding members 35 and 36.

Sputtering is performed with respect to substrate G in sputtering device 1 configured as described above. Since a basic principle of the sputtering is an already known technology, the description thereof will be omitted in the present specification. In sputtering device 1, ionized inert gas collides with the target, and as a result, particles (hereinafter, referred to as sputter particles) spattered and scattered from the target are accelerated in sputtering space 20 to be scattered toward substrate G from sputtering space 20.

The sputter particles scattered in a direction toward substrate G from sputtering space 20 move into light-shielding mechanism 30 (into passage 40 formed by shielding member 36). In addition, the sputter particles pass through passages 40, except that the sputter particles are reflected by light blocking body 31 or shielding members 35 and 36 in light-shielding mechanism 30, and collide with the surface of substrate G to be processed to perform sputtering with respect to substrate G. Sputtering with respect to substrate G is performed even by the sputter particles passing through passage 40 while being collided with and reflected from light blocking body 31 and shielding members 35 and 36.

Meanwhile, in the sputtering, inert gas is ionized by applying voltage between targets 10 and 11 to generate plasma. Magnetic field B is generated by magnetic bodies 17 and 18 in order to constrain the plasma. As the plasma is generated, light is emitted in sputtering space 20. In addition, the light is irradiated into light-shielding mechanism 30 through opening 37 by light emission in sputtering space 20. Light blocking body 31 having a width equal to or larger than the width of sputtering space 20 is placed in light-shielding mechanism 30 and light blocking body 31 is made of the material absorbing or reflecting light as described above, and as a result, the light irradiated into light-shielding mechanism 30 is absorbed in or reflected from light blocking body 31 not to reach substrate G.

Herein, specifically, when light blocking body 31 is made of a material that reflects light, since there is a possibility of that the reflected light may be reflected from shielding member 35 again to be irradiated to substrate G, shielding member 35 needs to be made of a material light can penetrate such as, for example, quartz as described above.

When light generated from sputtering space 20, specifically, ultraviolet rays having a short wavelength are irradiated to substrate G, the ultraviolet rays break the coupling of organic molecules within an organic thin film on substrate G on which the organic thin film has already been formed, thereby exerting a bad influence on a characteristic of the organic thin film. As a result, the characteristic of substrate G after sputtering is deteriorated to exert the bad influence on the characteristic of substrate G as a final product.

Therefore, the light irradiated to substrate G from sputtering space 20 is blocked by installing light-shielding mechanism 30 having the aforementioned configuration to efficiently acquire substrate G after sputtering, which has an excellent characteristic. That is, the sputtering with respect to substrate may be performed while preventing the characteristic of the organic thin film from being deteriorated by blocking the light from the sputtering space with respect to the substrate on which the organic thin film is formed as the object to be sputtered.

As set forth above, although one example of the exemplary embodiment of the present invention has been described, the present invention is not limited to the shown aspect. It is apparent to those skilled in the art that various changed examples or modified examples can be made within the scope of the spirit included in the appended claims and it is appreciated that the changed or modified examples are included in the scope of the present invention.

For example, in the above exemplary embodiment, although black alumite and aluminum are exemplified as light blocking body 31, light blocking body 31 is not limited thereto and, for example, light blocking body 31 may be made of a material having a property to absorb or reflect light having a shorter wavelength than visible rays. Further, although quartz is exemplified as the material for shielding members 35 and 36, a material in which light penetrates may be used and, for example, a material such as sapphire or transparent ceramics (YAG and Y₂O₃) may be used.

Further, in the above exemplary embodiment, although the cross-sectional shape of light blocking body 31 is lozenge, the shape is not limited thereto and for example, light blocking body 31 may have a shape in which surfaces absorbing or reflecting light face the bottom of the device, such as a triangular cross section which is convex toward the bottom of the device. That is, the cross-sectional shape of light block body 31 may be a shape not to reflect light toward a location where substrate G is placed. In this case, a gradient or a roughness degree of the surface absorbing or reflecting light may be appropriately set based on absorptance or reflectance when light is actually irradiated.

In addition, for example, when oxygen is deficient in the sputter particles in the case of film-forming electrodes such as indium tin oxide (ITO), indium zinc oxide (IZO), and aluminum zinc oxide (AZO) by sputtering, it is preferred that gas including oxygen molecules is supplied to the sputter particles. Therefore, an oxygen gas supply unit that supplies the gas including the oxygen molecules may be installed at a predetermined position of light blocking body 31, for example, a front end having the tapered shape of light blocking body 31 in the above exemplary embodiment.

Moreover, for example, inert gas such as Ar gas is ejected toward sputtering space 20 or passage 40 from light blocking body 31 and shielding members 35 and 36 to prevent the sputter particles from being attached to light blocking body 31 and shielding members 35 and 36. Therefore, as a first modified example of the present invention, a case where gas ejecting units 50 and 51 are formed in light blocking body 31 and shielding members 35 and 36, in light-shielding mechanism 30 according to the above exemplary embodiment, will be described with reference to FIG. 4. However, the same reference numerals refer to the same components as the above exemplary embodiment and the descriptions thereof will be omitted.

FIG. 4 is an explanatory view illustrating a light-shielding mechanism 30a according to a first modified example of the present invention. Gas ejecting units 50 and 50 are formed on the bottom of sputtering space 20 side of light blocking body 31 having a lozenge cross-sectional shape with ejection holes facing the bottom (a direction toward sputtering space 20). Further, gas ejecting units 51 and 51 are formed on the bottoms of shielding members 35 and 36, respectively, with the ejection holes facing passage 40.

Like the above exemplary embodiment, the sputter particles are scattered toward light blocking body 31 and passage 40 from sputtering space 20. As a result, the sputter particles collide with and are attached to light blocking body 31 or inner walls of shielding members 35 and 36. Accordingly, for example, the inert gas such as Ar is ejected from gas ejecting units 50 and 51 to prevent the sputter particles from colliding with and being attached to light blocking body 31 and shielding members 35 and 36. As a result, deposition of the sputter particles onto substrate G can be accelerated. A solid-line arrow in FIG. 4 indicates a gas ejection direction from gas ejecting units 50 and 51, and a dotted-line arrow indicates an example of a direction in which the sputter particles are spattered.

Herein, in light-shielding mechanism 30a shown in FIG. 4, gas ejecting units 50 and 51 are installed on the bottom of light blocking body 31 and the bottoms of shielding members 35 and 36, respectively, but the present invention is not limited thereto. It is preferred that installation locations of the gas ejecting units are appropriately changed considering flight directions of the sputter particles. For example, it may be considered that the gas ejecting units are formed at a plurality of locations including the bottom of light blocking body 31 or the bottoms of shielding members 35 and 36.

As described above, as the first modified example of the present invention, the case in which, for example, the inert gas such as Ar is ejected from gas ejecting units 50 and 51 is described, but when the gas including the oxygen molecules is supplied in order to prevent oxygen deficiency of the sputter particles, it may be considered that, for example, gas such as oxygen is ejected from the gas ejecting units.

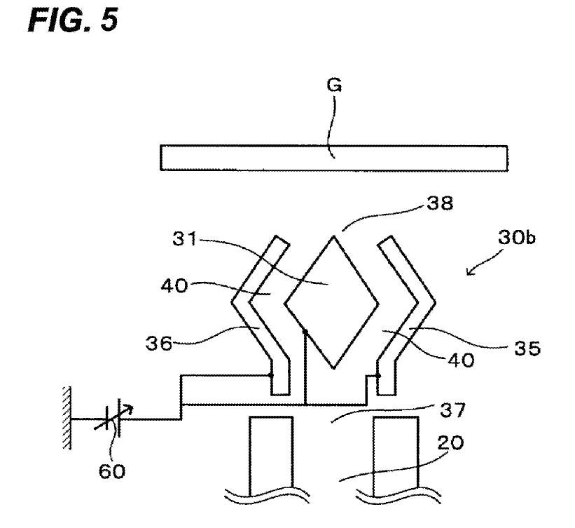

Further, variable power supplies capable of applying variable potentials may be connected to light blocking body 31 and shielding members 35 and 36, respectively. FIG. 5 is an explanatory view illustrating a light-shielding mechanism 30b according to a second modified example of the present invention. As shown in FIG. 5, in light-shielding mechanism 30b, a variable potential output electric power source 60 capable of applying variable voltage is connected to light blocking body 31 and shielding members 35 and 36, respectively.

In light-shielding mechanism 30b, the sputter particles scattered toward light blocking body 31 and shielding members 35 and 36 can be prevented from colliding and being attached by applying the variable voltage to light blocking body 31 and shielding members 35 and 36, and a result, it is possible to accelerate the deposition of the sputter particles onto substrate G. Herein, variable potential output electric power source 60 is connected to both of light blocking body 31 and shielding members 35 and 36, but variable potential output electric power source 60 may be connected to only one thereof.

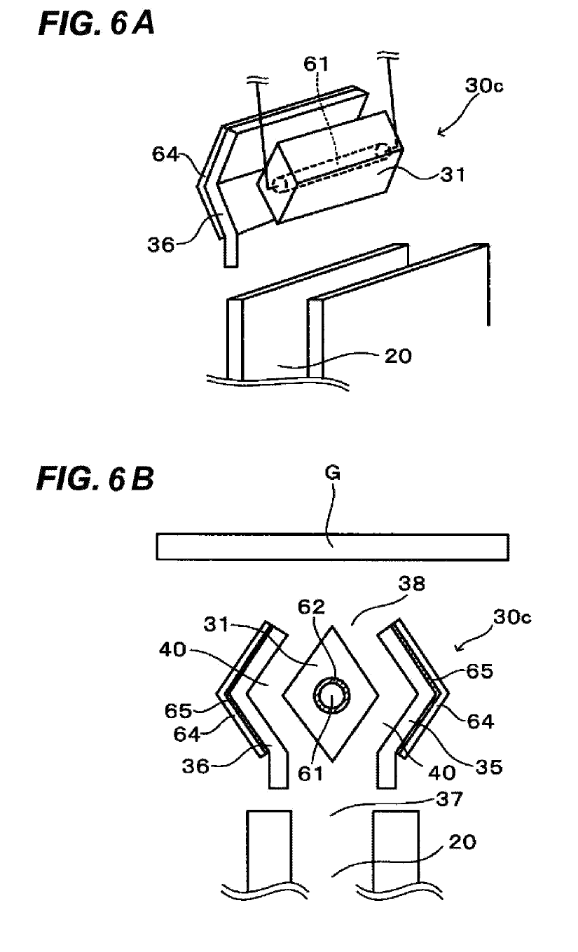

In the present invention, light blocking body 31 and shielding members 35 and 36 may be configured to be heated. FIGS. 6A and 6B are an explanatory view illustrating a light-shielding mechanism 30c according to a third modified example of the present invention, in which FIG. 6A is a perspective view and FIG. 6B is a cross-sectional view. As shown in FIGS. 6A and 6B, a substantially cylindrical heater 61 such as, for example, a cartridge heater is buried in an internal center of light blocking body 31, in light-shielding mechanism 30c. In FIG. 6A, only light blocking body 31 and shielding member 36 are shown for description and shielding member 35 and substrate G are not shown. Further, herein, a case is illustrated where heater 61 that extends in a lengthwise direction of light blocking body 31 having the lozenge cross-sectional shape is buried at the center of the lozenge cross section.

Further, as shown in FIGS. 6A and 6B, a plate-shaped heater 64 having a shape which matches the shapes of shielding members 35 and 36 is bonded to outer surfaces (side surfaces which do not face light blocking body 31) of shielding members 35 and 36. Heaters 61 and 64 are operated to heat light blocking body 31 and shielding members 35 and 36 to a desired temperature. Herein, the heating temperature is, for example, preferably in the range of 300° C. to 600° C., and needs to be a heating temperature at which temperature rising of substrate G by radiation heat from light blocking body 31 or shielding members 35 and 36 does not influence the film forming on the substrate. Specifically, it may be considered that the temperature is controlled so as not to heat substrate G or that the distance between substrate G and each heater is sufficiently maintained. The reason therefor is that when the temperature of substrate G is extremely increased by the radiation heat from light blocking body 31 or shielding member 35, sufficient precision in film forming using sputtering may not be acquired. Specifically, it is preferred that the rise in the temperature of substrate G by the radiation heat from light blocking body 31 or shielding member 35 is suppressed to 100° C. or less.

Although Al and black alumite are exemplified as the material for light blocking body 31 and quartz is exemplified as the material for shielding members 35 and 36 in the above exemplary embodiment, both light blocking body 31 and shielding members 35 and 36 are configured to be heated by heater 61 and heater 64, respectively, as described above, in light-shielding mechanism 30c in the present modified example, and as a result, it is preferred that, for example, materials such as stainless (SUS), copper (Cu), nickel (Ni), and aluminum (Al) through which light does not penetrate are used. However, when Al is used as the materials for light blocking body 31 and shielding members 35 and 36, for example, it is preferred that a heating temperature of approximately 350° C. or less is used so that Al is not deformed by heat. Further, in the present modified example, heaters 61 and 64 are installed at both sides of light blocking body 31 and shielding members 35 and 36, but the heater may be attached to only one thereof Furthermore, in the present modified example, light blocking body 31 and shielding members 35 and 36 are heated by heaters 61 and 64, but light blocking body 31 and shielding members 35 and 36 may be heated by lamp heating.

Further, as shown in FIG. 6B, heater 61 buried in light blocking body 31 is installed with carbon sheets 62 (not shown in FIG. 6A) composed of a plurality of layers wound on the periphery of the heater 61, and heaters 64 attached to the outer surfaces of shielding members 35 and 36 are bonded with a carbon sheet 65 interposed between the heaters 64 and shielding members 35 and 36, respectively. Carbon sheets 62 and 65 are interposed at a contact portion between heater 61 and light blocking body 31 and a contact portions between heaters 64 and shielding members 35 and 36 to improve thermal conductivity from each of heaters 61 and 64, thereby efficiently heating light blocking body 31 or shielding members 35 and 36.

When sputtering (film forming) is performed with respect to substrate G by the sputtering device including light-shielding mechanism 30c disclosed in FIGS. 6A and 6B described above, in addition to the operational effect in which sputtering can be performed while light from the sputtering space is blocked to prevent the characteristic of the organic thin film from being deteriorated with respect to the substrate as the object to be sputtered on which the organic thin film is formed, as described in the exemplary embodiment, an operational effect is provided in which light blocking body 31 or shielding members 35 and 36 are heated to prevent the sputter particles from colliding with and being attached to light blocking body 31 or shielding members 35 and 36. That is, the sputter particles are prevented from colliding with and being attached to light blocking body 31 or shielding members 35 and 36, and as a result, the number of the sputter particles reaching substrate G increases to efficiently accelerate the deposition of the sputter particles on substrate G. Furthermore, a device failure due to the attachment of the sputter particles to light blocking body 31 or shielding members 35 and 36 is prevented to achieve efficient sputtering.

### INDUSTRIAL APPLICABILITY

The present invention can be applied to a sputtering device.

1. A sputtering device performing sputtering with respect to a substrate placed on a lateral side of a sputtering space formed between a pair of targets facing each other, comprising:
an electric power source configured to apply voltage between the pair of targets;
a gas supply unit configured to supply inert gas to the sputtering space; and
a light-shielding mechanism configured to be placed between the sputtering space and the substrate.

2. The sputtering device of claim 1, wherein the light-shielding mechanism includes:
a light blocking body configured to reflect or absorb light between the sputtering space and the substrate; and
a shielding member configured to prevent placed sputter particles from being scattered by forming a passage through which the sputter particles pass toward the substrate between the shielding member and the light blocking body.

3. The sputtering device of claim 2, wherein a placement relationship is provided in which the sputtering space cannot be viewed from the substrate by interruption of the light blocking body and the shielding member.

4. The sputtering device of claim 1, wherein the electric power source is an AC electric power source that applies AC voltages having inverted phases to each other to the pair of targets.

5. The sputtering device of claim 4, wherein a frequency of the AC electric power source is in the range of 20 kHz to 100 kHz.

6. The sputtering device of claim 1, further comprising a magnetic body configured to generate a magnetic field in a direction perpendicular to the targets in the sputtering space.

7. The sputtering device of claim 2, wherein the light blocking body includes an oxygen gas supply unit that supplies gas including oxygen molecules.

8. The sputtering device of claim 2, wherein a front end of the light blocking body facing the sputtering space is formed in a tapered shape.

9. The sputtering device of claim 8, wherein the passage is curved on both sides of lateral sides of the light blocking body.

10. The sputtering device of claim 1, wherein the targets are made of aluminum, silver, ITO, or a transparent conductive material.

11. The sputtering device of claim 2, wherein the light blocking body is made of black alumite or aluminum.

12. The sputtering device of claim 2, wherein the shielding member is made of quartz.

13. The sputtering device of claim 2, wherein a variable potential output electric power source that applies a variable potential is connected to at least one of the light blocking body and the shielding member.

14. The sputtering device of claim 2, wherein a heater that heats at least one of the light blocking body and the shielding members is installed.

15. The sputtering device of claim 14, wherein a carbon sheet is interposed in a contact portion between the heater and at least one of the light blocking body and the shielding member.

16. The sputtering device of claim 14, wherein the light blocking body and the shielding member are made of any one of stainless, copper, nickel, and aluminum.
